(19) United States
(12) Patent Application Publication
(10) Pub. No.: US 2008/0258306 A1
(43) Pub. Date: Oct. 23, 2008

(54) Semiconductor Device and Method for Fabricating the Same

(75) Inventors: Chin-Huang Chang, Taichung (TW); Chien-Ping Huang, Taichung (TW); Chih-Ming Huang, Taichung (TW); Cheng-Hsu Hsiao, Taichung (TW); Cheng-Chia Chiang, Taichung (TW)

Correspondence Address: WPAT, PC;INTELLECTUAL PROPERTY ATTORNEYS, 2030 MAIN STREET, SUITE 1300, IRVINE, CA, 92614, US

(73) Assignee: SILICONWARE PRECISION INDUSTRIES CO., LTD., Taichung (TW)

(21) Appl. No.: 12/105,538

(22) Filed: Apr. 18, 2008

(30) Foreign Application Priority Data
Apr. 19, 2007 (TW) 096113749

(51) Int. Cl. H01L 23/538; H01L 21/56

(52) U.S. Cl. 257/762; 438/15; 257/E23.169; 257/E21.502

(57) ABSTRACT

The present invention provides a semiconductor device and a method for fabricating the same. The semiconductor device includes a chip having an active surface and an opposing non-active surface, wherein a plurality of bond pads are formed on the active surface, and first metal layers are formed on the bond pads and to edges of the non-active surface; conductive traces disposed on the non-active surface of the chip; a dielectric layer covering sides of the chip and formed with a plurality of openings therein to expose a portion of the conductive traces; and a plurality of second metal layers formed in the openings of the dielectric layer and on the first metal layers, such that the bond pads are electrically connected to the conductive traces via the first and second metal layers.

### BACKGROUND OF THE INVENTION

1. Field of the Invention

The present invention generally relates to semiconductor devices and methods for fabricating the same, and more particularly, to a semiconductor device that can be vertically stacked on another semiconductor device, and a method for fabricating the semiconductor device.

2. Description of Related Art

Multi-Chip Module (MCM) is a highly integrated form of semiconductor package and is characterized in having at least two chips mounted on a carrier (such as a substrate or lead frame) in a single semiconductor package. The MCM has been widely adopted in electronic devices (such as portable electronic products and associated peripheral products for communication, network and computer fields) for its advantages of enhancing the performance and capacity of the semiconductor package, thereby suitable for the electronic devices which are being made with low profile, large capacity and high speed.

FIG. 1 shows a conventional multi-chip semiconductor package having a plurality of horizontally spaced-apart chips. As shown in FIG. 1, the semiconductor package includes a substrate 100; a first chip 110 having an active surface 110a and an opposing non-active surface 110b, wherein the non-active surface 110b of the first chip 110 is attached to the substrate 100, and the active surface 110a of the first chip 110 is electrically connected to the substrate 100 by first bonding wires 120; and a second chip 140 spaced apart from the first chip 110 by a predetermined distance, the second chip 140 having an active surface 140a and an opposing non-active surface 140b, wherein the non-active surface 140b of the second chip 140 is attached to the substrate 100, and the active surface 140a of the second chip 140 is electrically connected to the substrate 100 by second bonding wires 150.

The aforementioned conventional multi-chip semiconductor packages has a critical drawback that the chips mounted on the substrate must be spaced apart from each other to avoid interference or undesirable contact between the bonding wires for the respective chips. Accordingly, a large die attachment area is required on the substrate for accommodating the chips especially when a large number of chips need to be incorporated in the semiconductor package. This undoubtedly causes cost increase and also is not favorable for profile miniaturization of the semiconductor package.

Referring to FIG. 2, U.S. Pat. No. 6,538,331 has disclosed a chip-stacked semiconductor package with a first chip 210 and a second chip 240 being stacked on a substrate 200. The overlying second chip 240 is offset from the underlying first chip 210 by a predetermined distance so as to facilitate formation of bonding wires connected from the first chip 210 and the second chip 240 respectively to the substrate 200.

Although the vertical chip-stacking arrangement of this semiconductor package is more spatially efficient than the horizontal chip arrangement of the above multi-chip semiconductor package, the need of bonding wires for electrical connection between the chips and the substrate makes such electrical connection susceptible to the length of the bonding wires and become degraded. Moreover, the offset arrangement of the vertically stacked chips and the provision of the bonding wires occupy a considerably large area on the substrate, thereby limiting the number of chips that can be mounted on the substrate.

U.S. Pat. Nos. 6,642,081, 5,270,261, and 6,809,421 have disclosed a method of vertically stacking and electrically connecting a plurality of semiconductor chips by means of through silicon via (TSV) technique. However, this technique is very complicated and has high cost, and thus is not commonly applicable in the industry.

U.S. Pat. Nos. 5,716,759, 6,040,235, 5,455,455, 6,646,289, and 6,777,767 have disclosed a chip having its upper and lower surfaces respectively formed conductive traces. This chip is fabricated from a wafer having a plurality of chips, wherein a cutting groove is formed on a non-active surface of the wafer, and bond pads formed on active surface of the chips are electrically connected to non-active surfaces of the chips by sputtering and redistribution layer (RDL) technique. However, with the cutting groove provided on the non-active surface (backside) of the wafer, positional alignment is not easily made, such that subsequently formed circuits may not be accurately positioned, and may adversely affect the electrical connection between the active and non-active surfaces of the chips and even damage the chips. Moreover, the RDL technique is applied multiple times during fabrication, thereby increasing the cost and process complexity. Further, as the fabrication process is performed directly on the wafer, no test for verifying whether the chips are “good dies” (non-defective chips) or not is conducted in advance, such that the fabrication process continues even if the wafer contains defective chips. This undesirably leads to material waste and increased cost.

Therefore, the problem to be solved here is to provide a semiconductor device that can effectively integrate more chips in the semiconductor device to enhance the electrical performance thereof, without increasing the die attachment area, without using bonding wires (which may cause degraded electrical connection), without using the TSV technique or multiple times of the sputtering technique (which may cause complicated processes and increased cost), and without performing the fabrication process directly on a wafer in the absence of the “good die” concern.

### SUMMARY OF THE INVENTION

In view of the aforementioned drawbacks, it is an objective of the present invention to provide a semiconductor device and a method for fabricating the same, which can integrate more chips in the semiconductor device without increasing the die attachment area.

It is another objective of the present invention to provide a semiconductor device and a method for fabricating the same, allowing the semiconductor device to be more simply fabricated, thereby avoiding complex processes and increased cost caused by multiple applications of sputtering.

It is still another objective of the present invention to provide a semiconductor device and a method for fabricating the same, allowing a plurality of semiconductor chips to be vertically stacked and electrically connected to each other, thereby avoiding poor electrical connection caused by wire-bonding technique.

It is a further objective of the present invention to provide a semiconductor device and a method for fabricating the same, allowing a plurality of semiconductor chips to be vertically stacked and electrically connected to each other, thereby avoiding complex processes and increased cost caused by TSV technique.

It is a further objective of the present invention to provide a semiconductor device and a method for fabricating the same, which can ensure that all chips use are “good dies”.

It is a further objective of the present invention to provide a semiconductor device and a method for fabricating the same, which have low cost and simple fabrication processes.

It is a further objective of the present invention to provide a semiconductor device and a method for fabricating the same, which may avoid damaging chips from a cutting groove formed on a backside of a wafer.

In order to attain the above and other objectives, the present invention provides a method for fabricating semiconductor devices, including the steps of: providing a wafer comprising a plurality of chips, each of the wafer and the chips having an active surface and an opposing non-active surface, and the active surface of each of the chips being formed with a plurality of bond pads thereon, and after each of the chips is determined to be a good die (i.e. a non-defective chip) by a chip probing (CP) test, forming a first metal layer on any adjacent two of the chips to electrically connect the bond pads of the adjacent chips to each other; performing a singulation process on the wafer to separate the chips, and mounting the chips on a surface of a carrier having a plurality of conductive traces disposed on the surface in a manner that gaps are formed between the adjacent chips, with a portion of the conductive traces being exposed from the gaps; forming a dielectric layer in the gaps, and forming a plurality of openings in the dielectric layer to expose the portion of the conductive traces; forming a resist layer over the chips and the dielectric layer, and forming a plurality of openings in the resist layer to expose the first metal layers on the chips and the openings of the dielectric layer; forming a plurality of second metal layers in the openings of the dielectric layer and in the openings of the resist layer, so as to allow the bond pads on the chips to be electrically connected to the conductive traces on the carrier by the first and second metal layers; and removing the resist layer, performing a singulation process along the dielectric layer between the chips, and removing the carrier, so as to separate the chips and allow the conductive traces to be exposed on the non-active surfaces of the chips, thereby forming the semiconductor devices.

Subsequently, the exposed conductive traces on the non-active surface of the chip in a semiconductor device can be stacked on and electrically connected to the second metal layers on the active surface of the chip in another semiconductor device, so as to form a multi-chip stacked structure.

All of the chips mounted on the carrier have been determined to be good dies (non-defective chips) before being mounted on the carrier. The chips are mounted on the carrier via an adhesive layer formed between the chips and the carrier. The first metal layers are formed on the active surfaces of the adjacent chips by means of a redistribution layer (RDL) technique, and are electrically connected to the bond pads of the adjacent chips. The carrier can be a metal board. The second metal layers, which are electrically connected to the first metal layers and the conductive traces, are formed in the openings of the dielectric layer and the openings of the resist layer by electroplating, so as to allow the bond pads on the active surfaces of the chips to be electrically connected to the conductive traces on the non-active surfaces of the chips by the first and second metal layers. The second metal layers include a copper layer, a nickel layer, and a solder material layer.

Moreover, after forming the second metal layers and removing the resist layer, an insulation layer can be formed on the active surfaces of the chips and the second metal layers, and then the carrier is removed, so as to form the semiconductor devices as thin chip scale package (CSP) devices. In addition, a plurality of conductive elements can be disposed on the conductive traces on the non-active surfaces of the chips, so as to allow the conductive elements to be electrically connected to an external device or used for directly stacking the semiconductor devices subsequently.

Further, during forming the first metal layers by the RDL technique, the first metal layers may have extending portions extended through the bond pads and towards the centers of the chips, and a plurality of extension pads can be formed at the ends of the extending portions of the first metal layers. The extension pads allow different electronic elements to be subsequently stacked or disposed thereon.

By the aforementioned method for fabricating semiconductor devices, the present invention further provides a semiconductor device, including: a chip having an active surface and an opposing non-active surface, wherein a plurality of bond pads are formed on the active surface of the chip, and first metal layers are formed on the bond pads and to edges of the active surface of the chip; conductive traces disposed on the non-active surface of the chip; a dielectric layer covering sides of the chip and formed with openings therein for exposing a portion of the conductive traces; and a plurality of second metal layers formed in the openings of the dielectric layer and on the first metal layers, so as to allow the bond pads on the chip to be electrically connected to the conductive traces by the first and second metal layers.

The semiconductor device may further include an insulation layer covering the active surface of the chip and the second metal layers, and a plurality of conductive elements disposed on outer surfaces of the conductive traces, so as to form a thin CSP device.

Therefore, the semiconductor device and the method for fabricating the same according to the present invention provides a carrier having a plurality of conductive traces disposed on a surface thereof, and a plurality of chips each having an active surface and an opposing non-active surfaces, wherein first metal layers are formed around edges of the active surface of the chip and are electrically connected to bond pads formed on the active surface of the chip. The chips are mounted on the carrier with gaps being left between the adjacent chips. The chips partially cover the conductive traces on the carrier. The gaps expose a portion of the conductive traces. The chips are determined to be good dies before being mounted on the carrier, such that material waste and increased cost, as observed in the prior arts, can be avoided. Then, a dielectric layer is formed and fills the gaps, and a plurality of openings are formed in the dielectric layer to expose the portion of the conductive traces. A resist layer is formed over the chips and the dielectric layer, and a plurality of openings are formed in the resist layer to expose the first metal layers on the bond pads and the openings of the dielectric layer. The second metal layers, which are electrically connected to the first metal layers and the conductive traces, are formed in the openings of the dielectric layer and the openings of the resist layers by electroplating. The bond pads on the active surfaces of the chips are electrically connected to the conductive traces on the non-active surfaces of the chips by the first and second metal layers. By this arrangement, complex processes and high cost in fabrication due to multiple applications of sputtering can be avoided. Then, the resist layer is removed, singulation is performed along the dielectric layer between the chips, and the carrier is removed, such that the chips are separated and the conductive traces are exposed on the non-active surfaces of the chips, thereby forming semiconductor devices of the present invention in a cost-effective and simplified way.

Subsequently, the conductive traces exposed on the non-active surface of the chip of a semiconductor device can be mounted on and electrically connected to a chip carrier, and the conductive traces exposed on the non-active surface of the chip of another semiconductor device can be mounted on and electrically connected to the second metal layers on the active surface of the chip of the previously described semiconductor device, so as to form a multi-chip stacked structure. This allows vertical stacking of semiconductor devices to take place without requiring an increased die attachment area, such that more chips can be effectively integrated to enhance the electrical performance of the semiconductor devices, and the problems encountered in the prior arts, such as degraded electrical connection associated with applying the wire-bonding technique and both complex processes and increased cost associated with using the TSV technique, can be avoided.

### BRIEF DESCRIPTION OF DRAWINGS

FIG. 1 is a cross-sectional schematic diagram showing a conventional multi-chip semiconductor package having a plurality of horizontally spaced-apart chips;

FIG. 2 is a cross-sectional schematic diagram showing a semiconductor package having multiple stacked chips as disclosed in U.S. Pat. No. 6,538,331;

FIGS. 3A to 3G are cross-sectional schematic diagrams showing a semiconductor device and a method for fabricating the same according to a first embodiment of the present invention;

FIG. 3D′ is a partial enlarged view of the structure in FIG. 3D;

FIG. 4 is a schematic diagram showing a stacked structure of semiconductor devices according to the first embodiment of the present invention;

FIGS. 5A and 5B are cross-sectional schematic diagrams showing a semiconductor device and a method for fabricating the same according to a second embodiment of the present invention;

FIG. 6 is a schematic diagram showing a stacked structure of semiconductor devices according to the second embodiment of the present invention;

FIGS. 7A to 7E are cross-sectional schematic diagrams showing a semiconductor device and a method for fabricating the same according to a third embodiment of the present invention; and

FIG. 8 is a schematic diagram showing a stacked structure of semiconductor devices according to a third embodiment of the present invention.

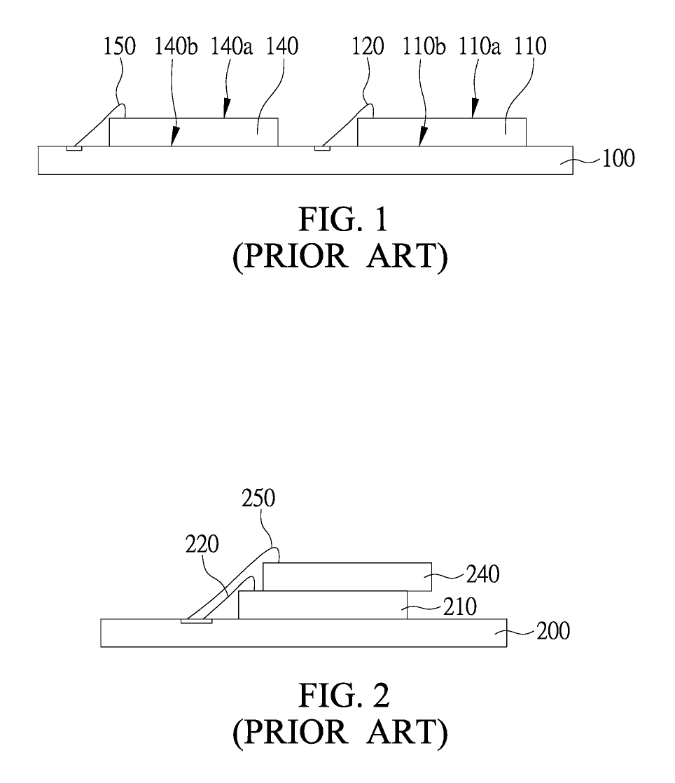

### DETAILED DESCRIPTION OF PREFERRED EMBODIMENTS

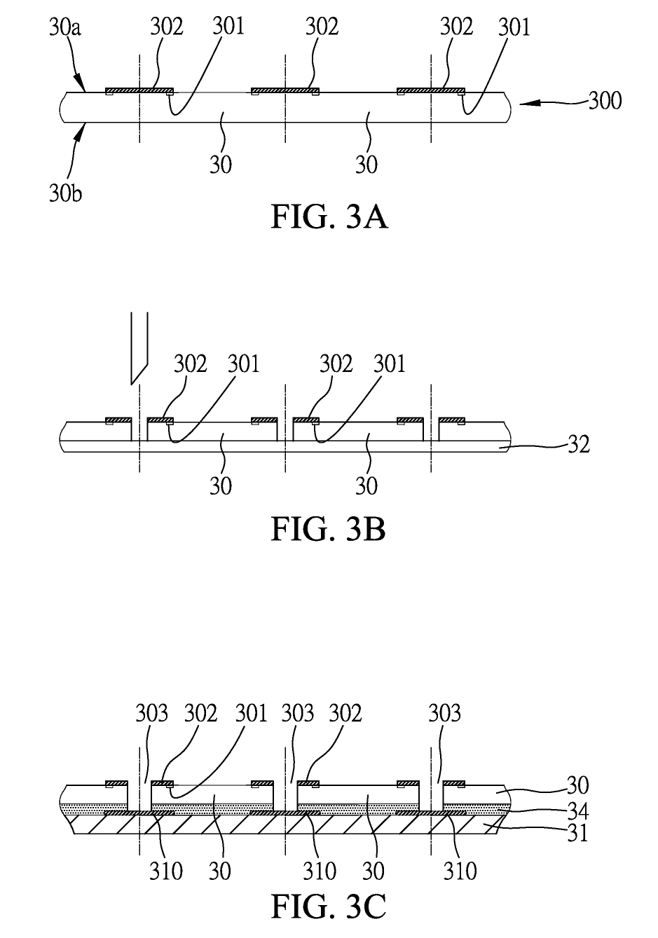

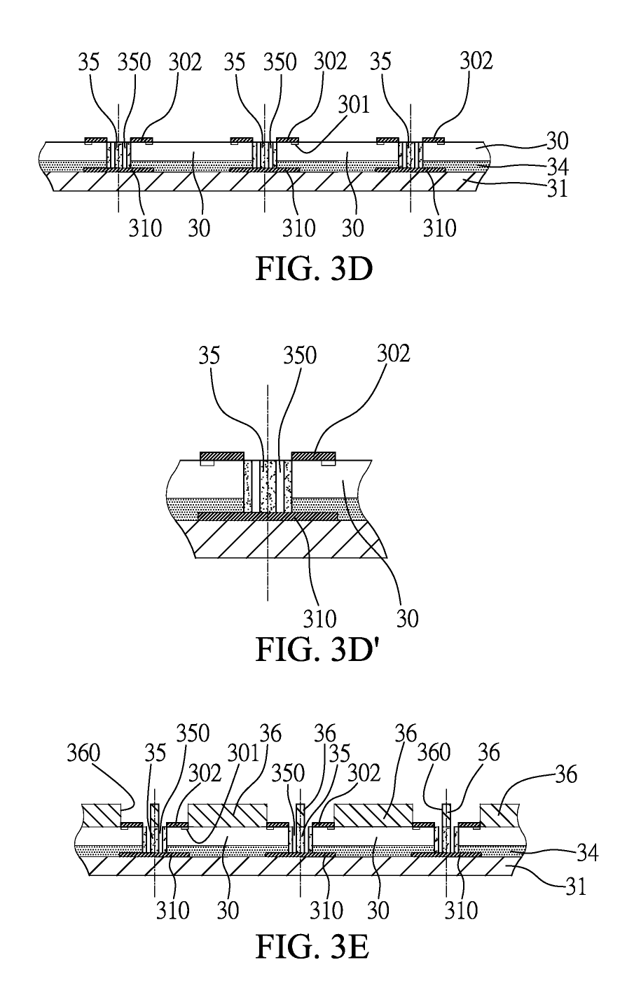

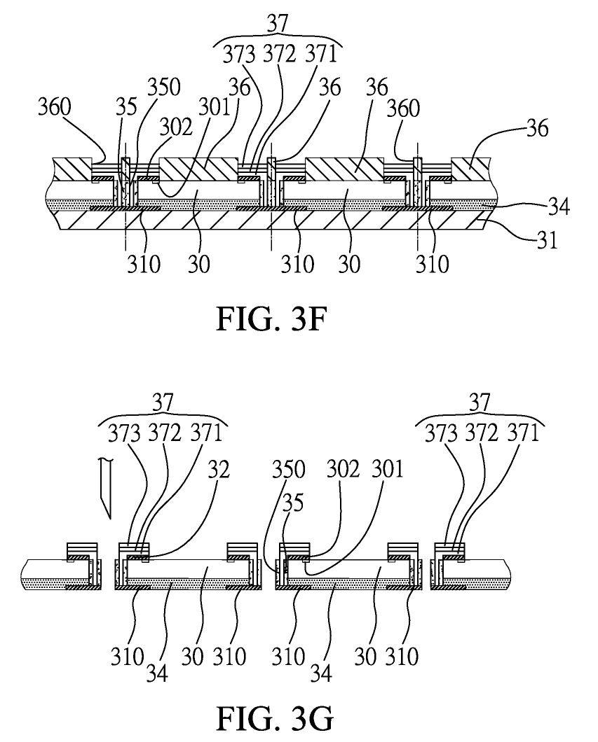

Preferred embodiments of a semiconductor device and a method for fabricating the same in the present invention are described as follows with reference to FIGS. 3 to 8. It should be understood that the drawings are schematic diagrams only showing relevant components in the present invention, and the practical component layout could be more complicated.

### First Embodiment

FIGS. 3A to 3G show a semiconductor device and a method for fabricating the same according to the first embodiment of the present invention.

As shown in FIGS. 3A and 3B, a wafer 300 has a plurality of chips 30. Each of the chips 30 and the wafer 300 has an active surface 30a and an opposing non-active surface 30b, wherein a plurality of bond pads 301 are formed on the active surface 30a of each of the chips 30. After a chip probing (CP) process is performed on each of the chips 30 to determine that the chips are good dies (non-defective chips), a first metal layer 302 is formed on any adjacent two of the chips 30 and is electrically connected to the bond pads 301 on the adjacent chips. The first metal layer 302 is, for example, an under bump metallurgy (UBM) layer made of titanium/copper/nickel (Ti/Cu/Ni), titanium tungsten/gold (TiW/Au), aluminum/nickel vanadium/copper (Al/NiV/Cu), titanium/nickel vanadium/copper (Ti/NiV/Cu), titanium tungsten/nickel (TiW/Ni), titanium/copper/copper (Ti/Cu/Cu), or titanium/copper/copper/nickel (Ti/Cu/Cu/Ni), etc.

Next, the non-active surface 30b of the wafer 300 is thinned to reduce the thickness of the wafer 300 to 25 to 100 μm. The wafer 300 is mounted on a tape 32 via the non-active surface thereof. The chips 30 are separated by performing singulation along the wafer 300 and the non-defective chips 30 are obtained.

As shown in FIG. 3C, an adhesive layer 34 is provided to attach the non-active surfaces 30b of the non-defective chips 30 to a surface of a carrier 31 (where a plurality of conductive traces 310 are disposed), with gaps 303 being formed between the adjacent chips 30. The chips 30 partially cover the conductive traces 310, and a portion of the conductive traces 310 is exposed from the gaps 303. The adhesive layer 34 may be a B-state epoxy resin layer.

The carrier 31 can be a metal board, such as a copper board, and the conductive traces 310 disposed on the surface thereof can be formed by electroplating. Each of the conductive traces 310 has a thickness of about 0.5 to 3 μm, and is made of, for example, gold/nickel/gold (Au/Ni/Au).

As shown in FIGS. 3D and 3D′, a dielectric layer 35 is formed in the gaps 303. The dielectric layer 350 may be made of epoxy resin or polyimide. A plurality of openings 350 are formed through the dielectric layer 35 by laser or etching, for exposing the portion of the conductive traces 310. The openings 350 through the dielectric layer 35 are spaced apart from sides of the chips 310, such that the dielectric layer 35 covers the sides of the chips 30 and provide insulation for subsequently formed metal layers.

As shown in FIG. 3E, a resist layer 36, such as a dry film, is formed on the chips 30 and the dielectric layer 35, and a plurality of openings 360 are formed through resist layer 36 to expose the first metal layers 302 on the chips 30 and the openings 350 of the dielectric layer 35.

As shown in FIG. 3F, a plurality of second metal layers 37 are deposited in the openings 350 and 360 by performing an electroplating process through the use of the metallic carrier 31 and the conductive traces 310 disposed thereon, such that the bond pads 301 on the chips 30 can be electrically connected to the conductive traces 310 via the first metal layers 302 and the second metal layers 37. The second metal layers 37 include a copper layer 371, a nickel layer 372, and a solder material layer 373. The copper layer 371 is first deposited in the openings 350 to cover the dielectric layer 35 and the first metal layers 302 on the chips 30, and then, the nickel layer 372 and the solder material layer 373 are deposited sequentially on the copper layer 371.

As shown in FIG. 3G, the resist layer 36 is removed, singulation is performed along the dielectric layer 35 between the chips 30, and the metallic carrier 31 is removed, for example, by etching, such that the chips 30 are separated and the conductive traces 310 are exposed on the non-active surfaces 30b of the chips 30, thereby forming a plurality of the semiconductor devices of the present invention.

By the aforementioned fabrication method, the present invention further provides a semiconductor device, includes: a chip 30 having an active surface 30a and an opposing non-active surface 30b, wherein a plurality of bond pads 301 are formed on the active surface 30a of the chip 30, and first metal layers 302 formed on the bond pads 301 and to edges of the active surface 30a of the chip 30; a plurality of conductive traces 310 disposed on the non-active surface 30b of the chip 30; a dielectric layer 35 covering sides of the chip 30 and having a plurality of openings 350 therein for exposing a portion of the conductive traces 310; and a plurality of second metal layers 37 formed in the openings 350 of the dielectric layer 35 and on the first metal layers 302, so as to allow the bond pads 301 to be electrically connected to the conductive traces 310 via the first metal layers 302 and the second metal layers 37. Additionally, an adhesive layer 34 can be formed between the non-active surface 30b of the chip 30 and the conductive traces 310, and the conductive traces 310 are formed in positions corresponding to edges of the adhesive layer 34.

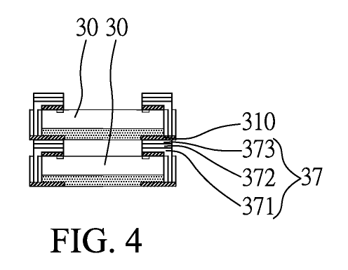

FIG. 4 shows vertical stacking of at least two of the above semiconductor devices by means of thermal compression. In the thermal compression process, a solder material in the second metal layers 37 formed on the active surface 30a of the chip 30 of one semiconductor device is fused with the conductive traces 310 disposed on the non-active surface 30b of the chip 30 of another semiconductor device, so as to form a multi-chip stacked structure. In addition, an underfill material (not shown) can fill a gap between the two semiconductor devices to enhance the bondability of the structure.

### Second Embodiment

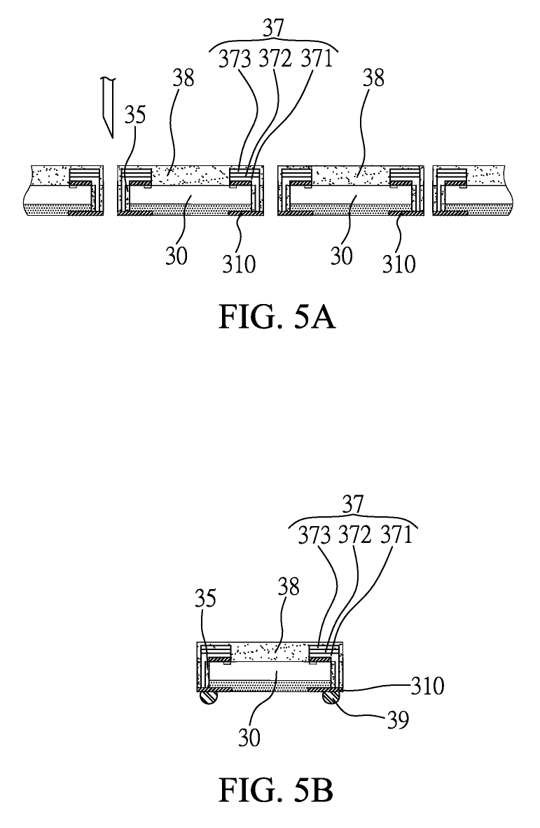

FIGS. 5A and 5B show a semiconductor device and a method for fabricating the same according to a second embodiment of the present invention. For brevity, as compared with the first embodiment, identical or similar elements are denoted with identical or similar reference numerals in the second embodiment.

The semiconductor device and its fabrication method in the second embodiment are similar to those in the first embodiment. The difference resides in that, as shown in FIG. 5A, after the second metal layers 37 are formed and the resist layer is removed, an insulating layer 38 is formed over the active surface of the chips 30 and the second metal layers 37. The insulating layer 38 can be an epoxy resin layer. Next, the carrier is removed by etching, and singulation is performed along the dielectric layer 35 to separate the chips 30. Consequently, a plurality of semiconductor devices such as thin CSP devices are formed.

As shown in FIG. 5B, a plurality of conductive elements 39, such as solder balls, can further be disposed on the conductive traces 310 on the non-active surface of the chip 30. The conductive elements 39 may be electrically connected to an external device subsequently.

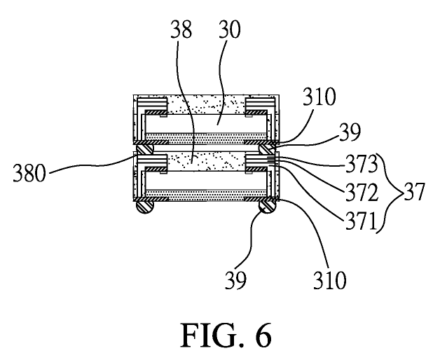

Referring to FIG. 6, a plurality of openings 380 can be formed through the insulating layer 38 of a semiconductor device, for exposing the second metal layers 37. The exposed second metal layers 37 are electrically connected to the conductive elements 39 disposed on the conductive traces 310 of another semiconductor device. As a result, a package-on-package stacked structure is formed.

### Third Embodiment

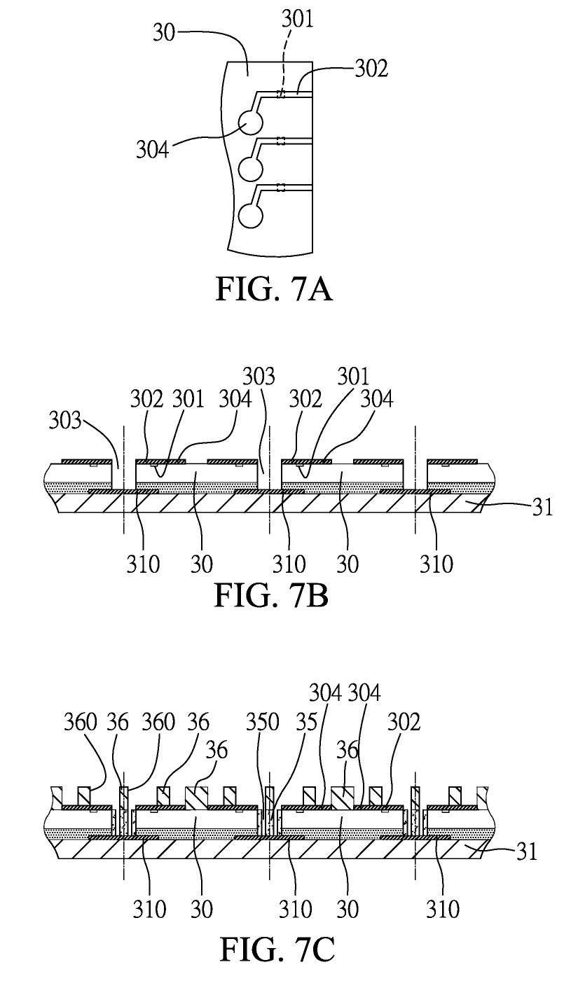

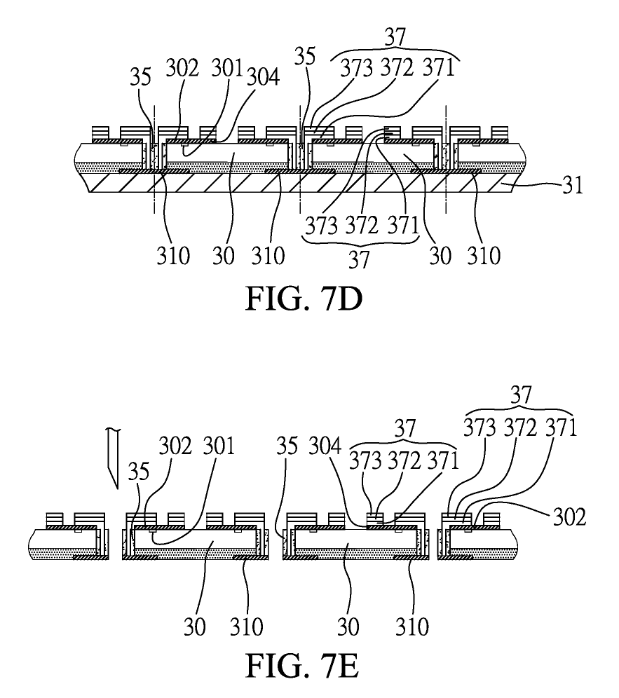

FIGS. 7A to 7E show a semiconductor device and a method for fabricating the same according to a third embodiment of the present invention. For brevity, as compared with the above embodiments, identical or similar elements are denoted with identical or similar reference numerals in the third embodiment.

The semiconductor device and its fabrication method in the second embodiment are similar to those in the above embodiments. The difference resides in that, as shown in FIG. 7A, when a plurality of first metal layers 302 are formed on the active surfaces of the chips 30 by means of the RDL technique, the first metal layers 302 can have extending portions extended through the bond pads 301 and towards the centers of the chips 30. A plurality of extension pads 304 are formed on at ends of the extending portions of the first metal layers 302.

As shown in FIG. 7B, similar to the descriptions in the above embodiments, the chips 30 are mounted on the carrier 31 having the conductive traces 310 disposed thereon, with gaps 303 being left between the adjacent chips 30, wherein the chips 30 cover partially the conductive traces 310, and a portion of the conductive traces 310 is exposed from the gaps 303.

As shown in FIG. 7C, a dielectric layer 35 is formed and fills the gaps 35, and openings 350 are formed through the dielectric layer 35. The openings 350 are used for exposing the portion of the conductive traces 310. Then, a resist layer 36 is formed on the chips 30 and the dielectric layer 35, and a plurality of openings 360 are formed through the resist layer 36. The openings 360 are used for exposing the first metal layers 302, the openings 350 and the extension pads 304.

As shown in FIG. 7D, the second metal layers 37 include, for example, a copper layer 371, a nickel layer 372, and a solder material layer 373, and are formed in the openings 350 of the dielectric layer 35 and on the first metal layers 302 and the extension pads 304 exposed from the openings 360. This allows the bond pads 301 to be electrically connected to the conductive traces 310 via the first metal layers 302 and the second metal layers 37. Afterwards, the resist layer 36 is removed.

As shown in FIG. 7E, singulation is performed along the dielectric layer 35 between the chips 30, and the carrier 31 is removed, thereby separating the chips 30 and allowing the conductive traces 310 to be exposed on the non-active surfaces of the chips 30, such that a plurality of semiconductor devices of the present invention are formed.

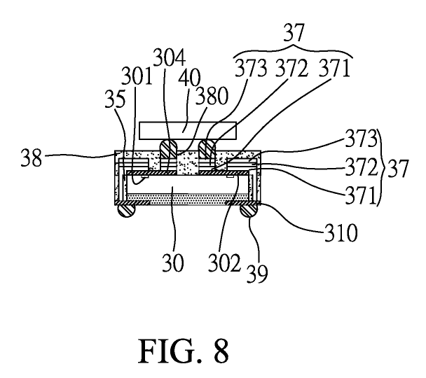

Referring to FIG. 8, an insulating layer 38 can further be formed on the active surface of the chip 30 and the second metal layers 37. A plurality of openings 380 are formed through the insulating layer 38 in positions corresponding to the extension pads 304, so as to allow different electronic elements 40 to be stacked on the second metal layers 37 subsequently. The conductive elements 39, such as solder balls, are disposed on the conductive traces 310 on the non-active surface of the chip 30, so as to allow the conductive elements 39 to be electrically connected to an external device.

Therefore, the semiconductor device and the method for fabricating the same according to the present invention provides a carrier having a plurality of conductive traces disposed on a surface thereof, and a plurality of chips each having an active surface and an opposing non-active surfaces, wherein first metal layers are formed around edges of the active surface of the chip and are electrically connected to bond pads formed on the active surface of the chip. The chips are mounted on the carrier with gaps being left between the adjacent chips. The chips partially cover the conductive traces on the carrier. The gaps expose a portion of the conductive traces. The chips are determined to be good dies before being mounted on the carrier, such that material waste and increased cost, as observed in the prior arts, can be avoided. Then, a dielectric layer is formed and fills the gaps, and a plurality of openings are formed in the dielectric layer to expose the portion of the conductive traces. A resist layer is formed over the chips and the dielectric layer, and a plurality of openings are formed in the resist layer to expose the first metal layers on the bond pads and the openings of the dielectric layer. The second metal layers, which are electrically connected to the first metal layers and the conductive traces, are formed in the openings of the dielectric layer and the openings of the resist layers by electroplating. The bond pads on the active surfaces of the chips are electrically connected to the conductive traces on the non-active surfaces of the chips by the first and second metal layers. By this arrangement, complex processes and high cost in fabrication due to multiple applications of sputtering can be avoided. Then, the resist layer is removed, singulation is performed along the dielectric layer between the chips, and the carrier is removed, such that the chips are separated and the conductive traces are exposed on the non-active surfaces of the chips, thereby forming semiconductor devices of the present invention in a cost-effective and simplified way.

Subsequently, the conductive traces exposed on the non-active surface of the chip of a semiconductor device can be mounted on and electrically connected to a chip carrier, and the conductive traces exposed on the non-active surface of the chip of another semiconductor device can be mounted on and electrically connected to the second metal layers on the active surface of the chip of the previously described semiconductor device, so as to form a multi-chip stacked structure. This allows vertical stacking of semiconductor devices to take place without requiring an increased die attachment area, such that more chips can be effectively integrated to enhance the electrical performance of the semiconductor devices, and the problems encountered in the prior arts, such as degraded electrical connection associated with applying the wire-bonding technique and both complex processes and increased cost associated with using the TSV technique, can be avoided.

The present invention has been described using exemplary preferred embodiments. However, it is to be understood that the scope of the present invention is not limited to the disclosed arrangements. The scope of the claims, therefore, should be accorded the broadest interpretation, so as to encompass all such modifications and equivalents.

What is claimed is:

1. A method for fabricating semiconductor devices, comprising the steps of:
providing a wafer comprising a plurality of chips, each of the wafer and the chips having an active surface and an opposing non-active surface, and the active surface of each of the chips being formed with a plurality of bond pads thereon, and after each of the chips is determined to be a good die by a chip probing (CP) process, forming a first metal layer on any adjacent two of the chips to electrically connect the bond pads of the adjacent chips to each other;
performing a singulation process on the wafer to separate the chips, and mounting the chips on a surface of a carrier having a plurality of conductive traces disposed on the surface in a manner that gaps are formed between the adjacent chips, with a portion of the conductive traces being exposed from the gaps;
forming a dielectric layer in the gaps, and forming a plurality of openings in the dielectric layer to expose the portion of the conductive traces;
forming a resist layer over the chips and the dielectric layer, and forming a plurality of openings in the resist layer to expose the first metal layers on the chips and the openings of the dielectric layer;
forming a plurality of second metal layers in the openings of the dielectric layer and in the openings of the resist layer, so as to allow the bond pads on the chips to be electrically connected to the conductive traces on the carrier by the first and second metal layers; and
removing the resist layer, performing a singulation process along the dielectric layer between the chips, and removing the carrier, so as to separate the chips and allow the conductive traces to be exposed on the non-active surfaces of the chips, thereby forming the semiconductor devices.

2. The method of claim 1, wherein the carrier is a metal board, and the conductive traces are formed on the surface of the carrier by electroplating and are made of gold/nickel/gold (Au/Ni/Au).

3. The method of claim 1, wherein the first metal layer is an under bump metallurgy (UBM) layer formed on the active surface of each of the chips by means of a redistribution layer (RDL) technique and is electrically connected to the bond pads of the adjacent chips, and the wafer is thinned, and the singulated chips are determined to be the good dies before they are mounted on the carrier.

4. The method of claim 1, wherein the chips are mounted on the carrier by an adhesive layer formed between the chips and the carrier.

5. The method of claim 1, wherein the dielectric layer is made of epoxy resin or polyimide, and the resist layer is a dry film.

6. The method of claim 1, wherein the openings of the dielectric layer are formed by laser or etching, and the openings of the dielectric layer are spaced apart from sides of the chips such that the sides of the chips are covered by the dielectric layer.

7. The method of claim 1, wherein the second metal layers comprise a copper (Cu) layer, a nickel (Ni) layer and a solder material layer, wherein an electroplating process is performed to deposit the copper layer in the openings of the dielectric layer and over the first metal layers and the dielectric layer, deposit the nickel layer on the copper layer, and deposit the solder material layer on the nickel layer.

8. The method of claim 1, wherein the second metal layers on the active surface of the chip of one of the semiconductor devices are electrically connected to the conductive traces on the non-active surface of the chip of another one of the semiconductor devices by a thermal compression process, so as to form a multi-chip stacked structure.

9. The method of claim 8, wherein a gap between the two semiconductor devices in the multi-chip stacked structure is filled with an underfill material.

10. The method of claim 1, further comprising after forming the second metal layers and removing the resist layer and before performing the singulation process along the dielectric layer and removing the carrier, forming an insulating layer on the active surfaces of the chips and the second metal layers.

11. The method of claim 10, wherein a plurality of conductive elements are disposed on outer surfaces of the conductive traces on the non-active surfaces of the chips.

12. The method of claim 11, wherein a plurality of openings are formed in the insulating layer to expose the second metal layers, so as to allow the exposed second metal layers to be electrically connected to the conductive elements disposed on the conductive traces in another one of the semiconductor devices.

13. The method of claim 1, wherein the first metal layers have extending portions extended through the bond pads and towards centers of the chips, and a plurality of extension pads are formed at ends of the extending portions of the first metal layers.

14. The method of claim 13, wherein the extension pads are exposed from the openings of the resist layer, and the second metal layers are formed in the openings of the dielectric layer and on the first metal layers and the extension pads exposed from the openings of the resist layer.

15. The method of claim 14, wherein an insulating layer is formed on the active surfaces of the chips and the second metal layers, a plurality of openings are formed in the insulating layer in positions corresponding to the extension pads to expose the second metal layers on the extension pads so as to allow electronic elements to be mounted on the exposed second metal layers, and a plurality of conductive elements are disposed on the conductive traces on the non-active surfaces of the chips.

16. A semiconductor device, comprising:
a chip having an active surface and an opposing non-active surface, wherein a plurality of bond pads are formed on the active surface of the chip, and first metal layers are formed on the bond pads and to edges of the active surface of the chip;
conductive traces disposed on the non-active surface of the chip;
a dielectric layer covering sides of the chip and formed with openings therein for exposing a portion of the conductive traces; and
a plurality of second metal layers formed in the openings of the dielectric layer and on the first metal layers, so as to allow the bond pads on the chip to be electrically connected to the conductive traces by the first and second metal layers.

17. The semiconductor device of claim 16, further comprising an adhesive layer formed between the non-active surface of the chip and the conductive traces, wherein the conductive traces are disposed in positions corresponding to edges of the adhesive layer.

18. The semiconductor device of claim 16, wherein the conductive traces are made of gold/nickel/gold (Au/Ni/Au), the dielectric layer is made of epoxy resin or polyimide, and the second metal layers comprise a copper (Cu) layer, a nickel (Ni) layer on the copper layer, and a solder material layer on the nickel layer.

19. The semiconductor device of claim 16, wherein the openings of the dielectric layer are spaced apart from the sides of the chip, such that the sides of the chip are covered by the dielectric layer.

20. The semiconductor device of claim 16, wherein the second metal layers on the active surface of the chip of the semiconductor device are electrically connected to the conductive traces disposed on the non-active surface of the chip of another semiconductor device in a multi-chip stacked structure.

21. The semiconductor device of claim 20, wherein a gap between the two semiconductor devices in the multi-chip stacked structure is filled with an underfill material.

22. The semiconductor device of claim 16, further comprising an insulating layer formed on the active surface of the chip and the second metal layers.

23. The semiconductor device of claim 22, further comprising a plurality of conductive elements disposed on outer surfaces of the conductive traces on the non-active surface of the chip.

24. The semiconductor device of claim 23, wherein a plurality of openings are formed in the insulating layer to expose the second metal layers, so as to allow the exposed second metal layers to be electrically connected to the conductive elements disposed on the conductive traces of the another semiconductor device.

25. The semiconductor device of claim 16, wherein each of the first metal layers is an under bump metallurgy (UBM) layer formed by a redistribution layer (RDL), and the chip is thinned and determined to be a good die.

26. The semiconductor device of claim 16, wherein the first metal layers have extending portions extended through the bond pads and towards a center of the chip, and a plurality of extension pads are formed at ends of the extending portions of the first metal layers.

27. The semiconductor device of claim 26, wherein the second metal layers are formed on the extension pads.

28. The semiconductor device of claim 27, further comprising an insulating layer formed over the active surface of the chip and the second metal layers, wherein a plurality of openings are formed in the insulating layer in positions corresponding to the extension pads to expose the second metal layers on the extension pads so as to allow electronic elements to be mounted on the exposed second metal layers, and a plurality of conductive elements are disposed on the conductive traces on the non-active surface of the chip.
